(19) United States
(12) Patent Application Publication
(10) Pub. No.: US 2022/0393430 A1
(43) Pub. Date: Dec. 8, 2022

(54) Semiconductor Optical Device

(71) Applicant: Nippon Telegraph and Telephone Corporation, Tokyo (JP)

(72) Inventors: Takuma Aihara, Musashino-shi, Tokyo (JP); Shinji Matsuo, Musashino-shi, Tokyo (JP); Tai Tsuchizawa, Musashino-shi, Tokyo (JP); Tatsuro Hiraki, Musashino-shi, Tokyo (JP)

(21) Appl. No.: 17/624,426

(22) PCT Filed: Jul. 9, 2019
(86) PCT No.: PCT/JP2019/027095

§ 371 Date: Jan. 3, 2022

(51) Int. Cl. H01S 5/12; H01S 5/026

(52) U.S. Cl. CPC H01S 5/124; H01S 5/026

(57) ABSTRACT

A semiconductor optical device includes a light emitting layer that emits light in a state of current injection; an optical waveguide in which a width or a thickness in an extending direction (y) of the light emitting layer varies along the extending direction; and a uniform diffraction grating having constant cycle, width and depth, wherein the light emitting layer, the optical waveguide and the uniform diffraction grating are arranged at positions where the light emitting layer, the optical waveguide, and the uniform diffraction grating are optically coupled to one another, the uniform diffraction grating is arranged above the light emitting layer, the optical waveguide is arranged below the light emitting layer, and the optical waveguide includes, in the extending direction, a first portion having a predetermined width, a second portion having a larger width than the width of the first portion, and a third portion having the same width as the width of the first portion.

### TECHNICAL FIELD

The present invention relates to a semiconductor optical device which can be applied to a semiconductor laser and the like.

### BACKGROUND ART

Communication traffic on the Internet and the like is increasing, and accordingly, high-speed and high-volume optical fiber transmission is being requested. The request is driving development of digital coherent communication technologies using coherent light communication technologies and digital signal processing technologies, which has practicalized 100-G systems. For such communication systems, single mode semiconductor lasers are needed as local oscillation light sources for communication and for reception.

A diffraction grating, for example, with λ/4 phase shift has been being used as a representative structure of an optical resonator for the single mode. This structure makes the phase inversed by a phase shifter formed in a part of a uniform diffraction grating and makes single mode oscillation at the Bragg wavelength possible. This sort of laser is called the λ/4 shift DFB (Distributed Feedback) laser, which has been already put into practical application.

There is a problem, as to the λ/4 shift DFB laser, that its spectral line width is prevented from being narrowed, due to a phenomenon called spatial hole burning that a carrier distribution arises in the resonator caused by an optical intensity distribution in the laser. There is disclosed against this a laser in which a distributed reflector (DR) diffraction grating is formed to obtain a high reflectance, for example, in Non-Patent Literature 1. Moreover, there is disclosed a cycle modulated (Corrugation Pitch Modulated) diffraction grating which relieves localization of an optical intensity distribution in the active layer by making a phase shift moderate, for example, in Non-Patent Literature 2.

In optical communication using a phase signal, laser's line width, which affects signal quality, is important and a narrower line width thereof is said to be better. It is known that reducing a resonator loss in a semiconductor laser is effective for achieving laser with a narrow spectral line width.

### CITATION LIST

### Non-Patent Literature

Non-Patent Literature 1: T. Simoyama et al., “40-Gbps Transmission Using Direct Modulation of 1.3-μm AlGaInAs MQW Distributed-Reflector Lasers up to 70° C”, OFC/NFOEC 2011, OWD3, 2011.

Non-Patent Literature 2: M. Okai et al., “Corrugation-Pitch-Modulated MQW-DFB Laser with Narrow Spectral Linewidth (170 Khz)”, IEEE Photonics Technology Letters, vol. 2, no. 8, pp. 529-530, 1990.

### SUMMARY OF THE INVENTION

### Technical Problem

However, reducing a resonator loss to enhance the Q value of the resonator causes light to be strongly localized to a phase shift region. Many carriers are consumed in this region where the light is strongly localized, and density of the carriers decreases there. Such a decrease in carrier density results in an increase in refractive index and causes a distribution of the refractive index to arise inside the resonator.

The distribution of the refractive index results in a decrease in reflectance of the resonator and a decrease in mode selectivity and causes the oscillation mode of laser to be unstable. There is a problem on the λ/4 shift DFB laser as above that the line width is prevented from being narrowed, due to the spatial hole burning. Moreover, since as to the DFB laser disclosed in Non-Patent Literature 1, the oscillation wavelength of DFB is largely displaced from the reflection wavelength of DR in the state of current injection, it is difficult to obtain single mode oscillation stably across a wide current region.

Moreover, since as to the structure of the cycle modulated diffraction grating disclosed in Non-Patent Literature 2, the cycles of the diffraction grating are different between the phase modulation region and the other, unevenness tends to arise in its production process such as etching and crystal growth, which makes the production difficult.

The present invention is devised in view of such a problem, and an object thereof is to provide a semiconductor optical device capable of making spatial hole burning scarcely occur and making a spectral line width narrow.

### Means for Solving the Problem

On a semiconductor optical device according to an aspect of the present invention, the point is to include: a light emitting layer that emits light in a state of current injection; an optical waveguide in which a width or a thickness in an extending direction of the light emitting layer varies along the extending direction; and a uniform diffraction grating having constant cycle, width and depth.

### Effects of the Invention

According to the present invention, there can be provided a semiconductor optical device capable of making spatial hole burning scarcely occur and making a spectral line width narrow.

### BRIEF DESCRIPTION OF DRAWINGS

FIG. 1 shows a schematic exemplary configuration of a semiconductor optical device according to an embodiment of the present invention.

FIG. 2 is a view exemplarily showing a planar shape of an optical waveguide shown in FIG. 1.

FIG. 3 is a diagram schematically showing a situation where a stop band of the semiconductor optical device shown in FIG. 1 takes an offset.

FIG. 4 is a diagram exemplarily showing a transmission spectrum of a stop band obtained by modulating a refractive index.

FIG. 5 is a diagram showing exemplary calculation of a threshold gain of a semiconductor laser having a refractive index modulated diffraction grating.

FIG. 6 is a diagram showing exemplary calculation of an optical intensity distribution of an optical waveguide of a semiconductor optical device according to an embodiment of the present invention in an extending direction.

FIG. 7 is a view exemplarily showing a more specific sectional configuration of the semiconductor optical device shown in FIG. 1.

FIG. 8 is a diagram showing exemplary calculation of relationships between a modulation depth and threshold gains.

FIG. 9 schematically shows a situation where refractive indices of an optical waveguide at both end portions thereof relatively decrease due to spatial hole burning.

FIG. 10 exemplarily shows a planar shape of an optical waveguide caused to have spatial hole burning tolerance.

FIG. 11 exemplarily schematically shows offsets X and Y of a stop band.

FIG. 12 is a diagram exemplarily showing calculation of relationships between the offset X and a threshold gain in a fundamental mode with the offset Y of the stop band being as a parameter.

FIG. 13 is a diagram exemplarily showing calculation of differences between the threshold gain in the fundamental mode shown in FIG. 12 and a threshold gain in a higher-order mode.

FIG. 14 is a view schematically showing a modification of the optical waveguide shown in FIG. 1.

FIG. 15 schematically shows a modification of a uniform diffraction grating shown in FIG. 1.

FIG. 16 is a view exemplarily schematically showing a band offset with which a long wavelength side is selected.

FIG. 17 is a view schematically showing another modification of the optical waveguide shown in FIG. 1.

### DESCRIPTION OF EMBODIMENTS

Hereafter, embodiments of the present invention are described using the drawings. The same components in the drawings are given the same reference numerals and are not repetitively described.

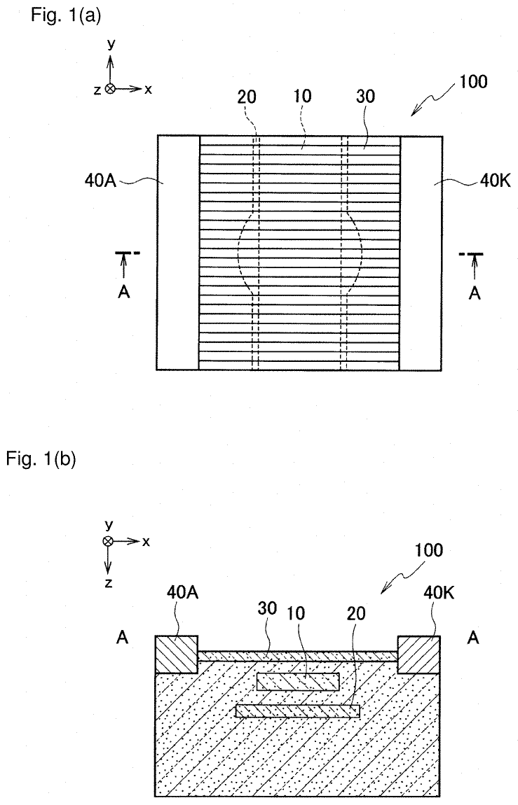

FIG. 1 shows a schematic exemplary configuration of a semiconductor optical device according to an embodiment of the present invention. A semiconductor optical device 100 shown in FIG. 1 is a semiconductor laser which emits laser light.

FIG. 1(a) is a plan view and FIG. 1(b) is a sectional view taken along the A-A line shown in FIG. 1(a). The thickness direction is defined as z, the right-left direction as x, and the direction of going farther as y.

As shown in FIG. 1, the semiconductor optical device 100 includes a light emitting layer 10, an optical waveguide 20 and a uniform diffraction grating 30. Reference numeral 40A denotes an anode electrode, and reference numeral 40K denotes a cathode electrode.

The light emitting layer 10 emits laser light in the state of current injection. The current is caused to flow from the anode electrode 40A toward the cathode electrode 40K. The laser light is emitted in the y-direction.

As to the optical waveguide 20, its width in the direction (x) perpendicular to the extending direction (y) of the light emitting layer 10 varies along the extending direction (FIG. 1(a)). The material of the optical waveguide 20 is exemplarily silicon.

The uniform diffraction grating 30 has constant cycle, width and depth. The uniform diffraction grating 30 is arranged along the extending direction (y) of the light emitting layer 10 such that the cycle, width and depth are constant in the direction (x) perpendicular to the extending direction. The material of the uniform diffraction grating 30 is exemplarily SiN. The uniform diffraction grating 30 constitutes a resonator.

The light emitting layer 10, the optical waveguide 20 and the uniform diffraction grating 30 are arranged at positions where the light emitting layer 10, the optical waveguide 20, and the uniform diffraction grating 30 are optically coupled to one another. In other words, they are arranged at intervals at which their optical modes overlap.

Since the optical modes overlap, the effective refractive index of the semiconductor laser varies along the extending direction (y) of the optical waveguide 20 due to the variation in width of the optical waveguide 20. The effective refractive index is the refractive index determined based on the refractive indices of the materials within a range where the optical modes overlap and a carrier concentration.

The variation of the effective refractive index changes a stop band, which is a cutoff frequency of the uniform diffraction grating 30 (resonator). For example, the stop band can be changed by causing the width of the optical waveguide 20 to vary such that the effective refractive index is high at the center thereof in the y-direction.

FIG. 2 is a view exemplarily showing a planar shape of the optical waveguide 20. The optical waveguide 20 shown in FIG. 2 includes, in the extending direction (y), a first portion 20a having a predetermined width, a second portion 20b having a larger width than the width of the first portion 20a, and a third portion 20c having the same width as the width of the first portion 20a, and includes a width widening region 20d connecting smoothly between the first portion 20a and the second portion 20b, and a width narrowing region 20e connecting smoothly between the second portion 20b and the third portion 20c.

When the planar shape of the optical waveguide 20 is a shape exemplarily shown in FIG. 2, the effective refractive index at the center of the optical waveguide 20 in the y-direction is high. The high effective refractive index causes the wavelength of the stop band at the relevant portion in the uniform diffraction grating 30 (resonator) to shift to the long wavelength side.

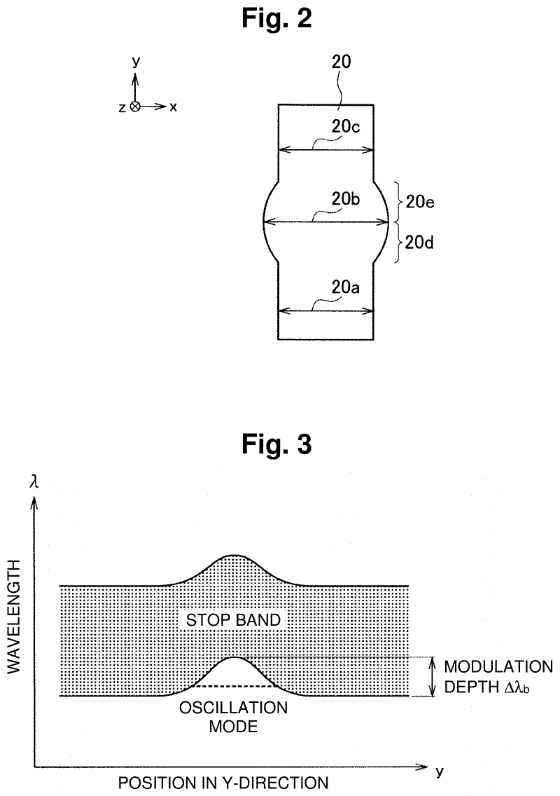

FIG. 3 is a diagram schematically showing a situation where the stop band of the uniform diffraction grating 30 takes an offset. The horizontal axis represents a position in the y-direction, and the vertical axis represents a Bragg wavelength.

As shown in FIG. 3, the wavelength of the stop band at the center portion of the optical waveguide 20 in the y-direction shifts (has an offset) to the long wavelength side. Light that meets phase conditions in this stop band with the offset is to be localized in the second portion 20b with the largest width within the optical waveguide 20.

The semiconductor optical device 100 oscillates at a specific wavelength of the localized light and emits laser light with the wavelength. FIG. 3 schematically shows the specific wavelength with a thin dotted line.

Simply with use of the uniform diffraction grating 30, the semiconductor optical device 100 is to oscillate at wavelengths at the ends of the stop band both on the long wavelength side and the short wavelength side. Nevertheless, by causing the stop band of the uniform diffraction grating 30 to have an offset, laser oscillation in a single mode can be realized.

The configuration including the optical waveguide 20 and the uniform diffraction grating 30 according to the present embodiment is hereinafter called refractive index modulated diffraction grating. Moreover, the offset amount of the stop band of the uniform diffraction grating 30 represents a modulation depth Δλ_{b} of the refractive index (FIG. 3).

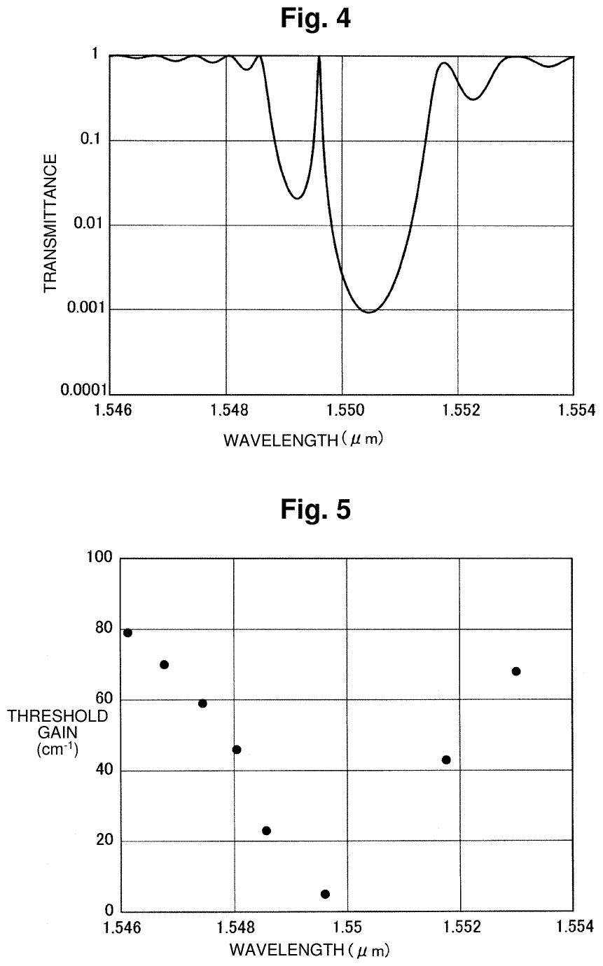

FIG. 4 is a diagram showing a transmission spectrum of the stop band of the uniform diffraction grating 30. The horizontal axis represents a wavelength (μm), and the vertical axis represents a transmittance. As shown in FIG. 4, the uniform diffraction grating 30 shows transmission characteristics in which a Q value is high at 1.549 μm of wavelength.

FIG. 5 is a diagram showing a threshold gain of the semiconductor optical device 100. The horizontal axis is the same as in FIG. 4. The vertical axis represents the threshold gain (cm⁻¹). It is clear as shown in FIG. 5 that the threshold gain is lowest at 1.549 μm of wavelength.

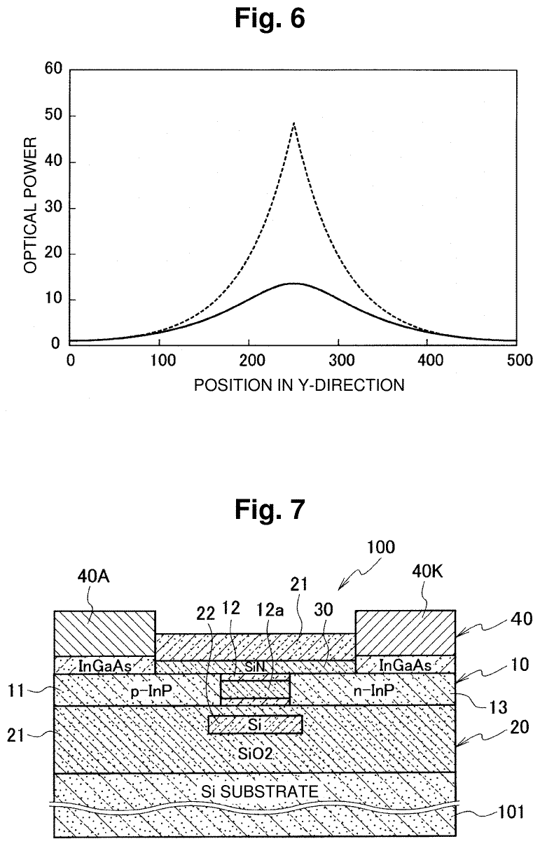

FIG. 6 is a diagram showing an optical intensity distribution of the optical waveguide 20 along the y-direction. The horizontal axis represents a position in the y-direction, and the vertical axis represents an optical power. Notably, the dotted line shows an optical intensity distribution of a general λ/4 shift diffraction grating.

It is clear as shown in FIG. 6 that localization of light at the center of the optical waveguide 20 according to the present embodiment in the y-direction is relieved. The localization of light is relieved, thereby, the spatial hole burning can be made scarcely occur, and the oscillation mode can be restrained from being unstable.

Notably, while as to the optical waveguide 20, there has been presented an example in which its width in the direction (x) perpendicular to the extending direction (y) is caused to vary along the extending direction, its thickness in the extending direction may be caused to vary. The same operation and effects as in the case of causing the width in the extending direction to vary can be obtained.

As described above, the semiconductor optical device 100 according to the present embodiment includes: the light emitting layer 10 which emits light in the state of current injection; the optical waveguide 20 in which the width or the thickness in the extending direction of the light emitting layer 10 varies along the extending direction; and the uniform diffraction grating 30 having the constant cycle, width and depth, and the light emitting layer 10, the optical waveguide 20, and the uniform diffraction grating 30 are arranged at the positions where the light emitting layer 10, the optical waveguide 20, and the uniform diffraction grating 30 are optically coupled to one another. Moreover, the uniform diffraction grating 30 is arranged above the light emitting layer 10, and the optical waveguide 20 is arranged below the light emitting layer 10.

Moreover, the optical waveguide 20 includes, in the extending direction, the first portion 20a having the predetermined width, the second portion 20b having the larger width than the width of the first portion 20a, and the third portion 20c having the same width as the width of the first portion 20a, and includes the width widening region 20d connecting smoothly between the first portion 20a and the second portion 20b, and the width narrowing region 20e connecting smoothly between the second portion 20b and the third portion 20c.

The refractive index modulating diffraction grating thereby can realize a semiconductor optical device which has higher spatial hole burning tolerance than a λ/4 shift diffraction grating and is effective for achieving laser light with the narrow line width. Moreover, since the uniform diffraction grating 30 is used, the production is easier than in the case using a λ/4 shift diffraction grating or a cycle modulated diffraction grating, and the production yield of semiconductor optical devices can be improved, resulting in cost reduction.

### (Sectional Configuration of Semiconductor Optical Device)

FIG. 7 is a view exemplarily showing a more specific sectional configuration of the semiconductor optical device 100. The semiconductor optical device 100 shown in FIG. 7 is obtained by stacking a Si substrate 101, the optical waveguide 20, the light emitting layer 10, the uniform diffraction grating 30 and an electrode unit 40 from the lower layer in the z-direction. Each layer has a shape long in the direction (y) of going farther in the figure.

The optical waveguide 20 includes a cladding layer 21 composed of a SiO₂ film, and a silicon core 22 enclosed by the cladding layer 21. The silicon core 22 is arranged on the layer's upper side close to the light emitting layer 10. The optical waveguide 20 has the planar shape shown in FIG. 2.

The light emitting layer 10 includes an I layer 12 between p-type InP (p-InP) 11 and n-type InP (n-InP) 13 which are doped with impurities. The I layer 12 is intrinsic semiconductor and includes an active layer 12a. The material of the active layer 12a is exemplarily InGaAsP. Notably, the light emitting layer 10 shown in FIG. 1 corresponds to the active layer 12a.

The p-type InP 11 is ohmically connected to the anode electrode 40A via an InGaAs film. The n-type InP 13 is ohmically connected to the cathode electrode 40B via an InGaAs film.

The uniform diffraction grating 30 is arranged on surfaces of the entire I layer 12 and a part of the p-type InP 11 and at the position of the n-type InP 13. The uniform diffraction grating 30 is a diffraction grating in which the duty ratio between the cycle and the width and the depth are constant.

### (Characteristics of Semiconductor Optical Device)

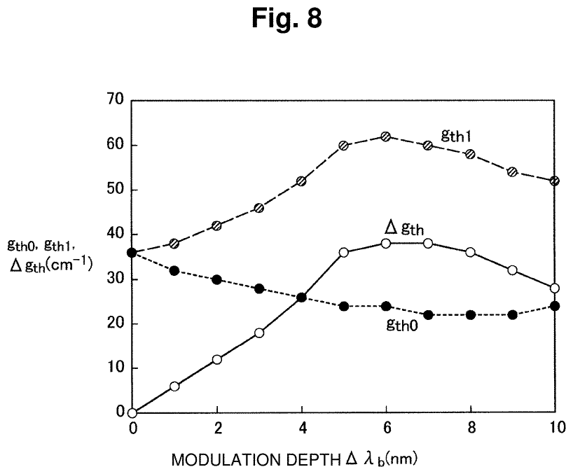

FIG. 8 exemplarily shows results of calculation of relationships of the modulation depth Δλ_{b} to a threshold gain gth0 in a fundamental mode, a threshold gain gth1 in a higher-order mode, and a gain difference Δgth between the threshold gain gth0 and the threshold gain gth1. As shown in FIG. 8, when the modulation depth Δλ_{b} is increased, the threshold gain gth0 in the fundamental mode decreases. Moreover, when the modulation depth Δλ_{b} is increased, the threshold gain gth1 in the higher-order mode increases and then decreases.

The reason why the threshold gain gth1 in the higher-order mode increases is that the oscillation mode on the long wavelength side is restrained by the offset of the stop band. Moreover, it is considered the reason why the threshold gain gth1 then decreases is that the higher-order mode is generated in the stop band.

It is clear as shown in FIG. 8 that in order to increase the threshold gain difference Δgth to realize stable single mode oscillation, an adequate modulation depth Δλ_{b} is necessary.

### (Configuration to Enhance Spatial Hole Burning Tolerance)

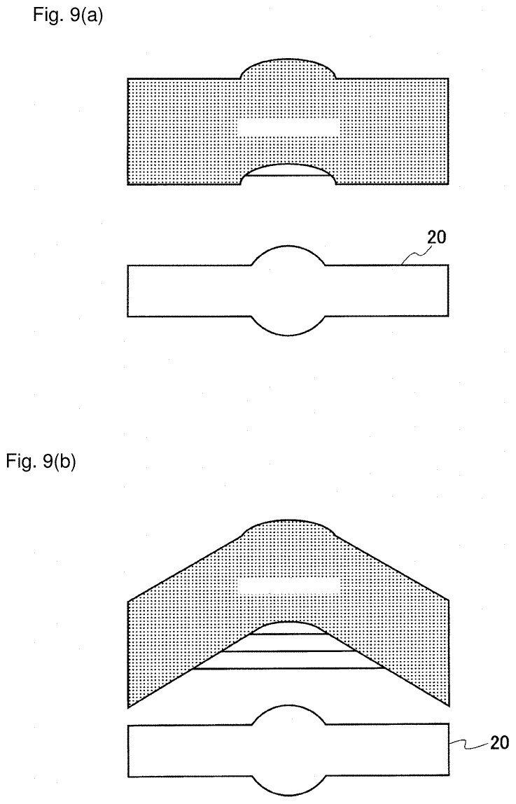

FIG. 9 schematically shows a situation where refractive indices of the optical waveguide 20 at both end portions thereof in the extending direction relatively decrease due to the spatial hole burning. In FIG. 9, upper views show relationships between the position (horizontal axis) of the optical waveguide 20 in the y-direction and the Bragg wavelength (vertical axis). Lower views therein schematically show the planar shape of the optical waveguide. FIG. 9(a) shows a case before current is injected, and FIG. 9(b) shows a case where current is injected.

As shown in FIG. 9(b), when current is injected, the refractive indices of the optical waveguide 20 at both end portions relatively decrease due to the spatial hole burning. The decrease in the refractive indices results in decrease in the Bragg wavelength.

Such a refractive index distribution in which the refractive indices of the optical waveguide 20 at both end portions decrease makes the oscillation mode unstable. It is therefore reasonable to enlarge the widths at both end portions of the optical waveguide 20 in advance so as to cancel the refractive index distribution in which the refractive indices at both end portions decrease.

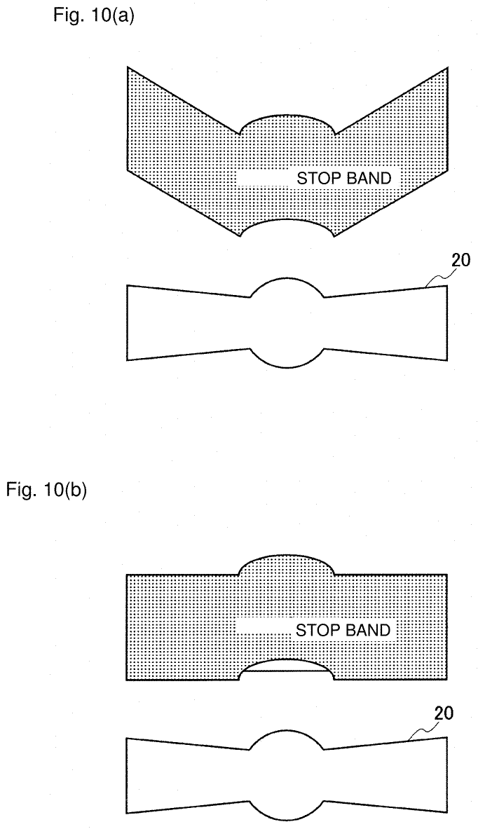

FIG. 10 schematically shows an example in which the widths of the optical waveguide 20 at both end portions are enlarged. FIG. 10(a) shows a case before current is injected, and FIG. 10(b) shows a case where current is injected.

As shown in FIG. 10, enlarging the widths of the optical waveguide 20 at both end portions causes the change in refractive index distribution due to the spatial hole burning during current injection and the refractive index distribution provided by enlarging the widths of the optical waveguide 20 at both end portions to offset each other, affording a uniform refractive index distribution. In other words, spatial hole burning tolerance can be enhanced.

As above, the widths of the optical waveguide 20 at both end portions in the extending direction are enlarged more than a predetermined width inward of these end portions. This enables stable single mode oscillation during current injection. This configuration is effective especially for the cases where large current is injected.

(Configuration to Enhance Threshold Gain Difference between Fundamental Mode and Higher-Order Mode)

It has been already explained that in order to realize the narrow line width, reducing a resonator loss is effective. In order to reduce a resonator loss in the fundamental mode, it is needed to enhance the coupling factor of the uniform diffraction grating 30 or to enlarge the length of the uniform diffraction grating 30.

However, either enhancing the coupling factor of the uniform diffraction grating 30 or enlarging the length of the uniform diffraction grating 30 lowers the threshold gain in the higher-order mode, which makes multimode oscillation easily occur. It is therefore desirable to lower the threshold gain in the fundamental mode, and meanwhile, to enhance the threshold gain difference thereof from that in the higher-order mode.

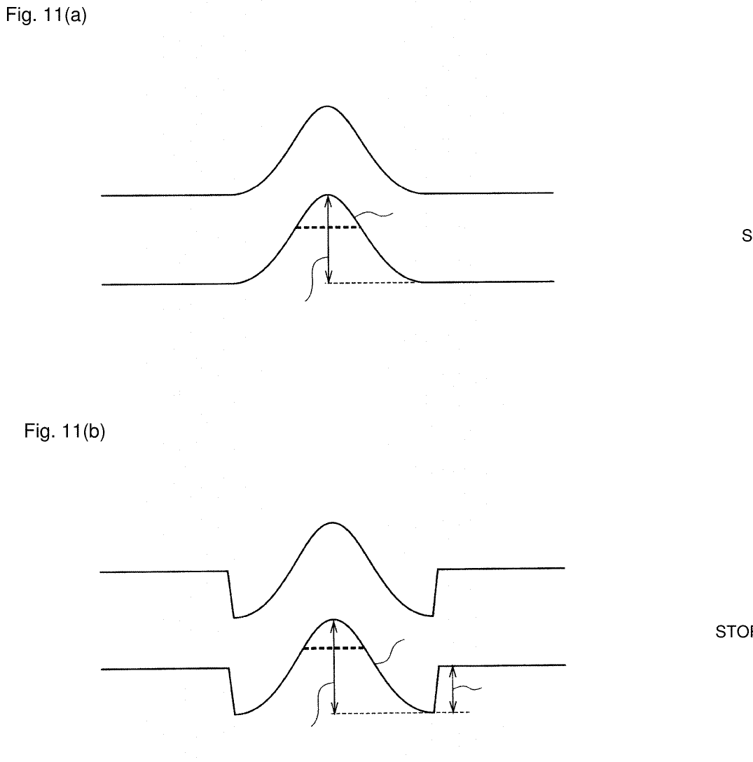

FIG. 11 exemplarily shows a specific measure for this. FIG. 11(a) schematically shows a situation where the stop band of the uniform diffraction grating 30 takes an offset, and is the same as FIG. 3. The offset shown in FIG. 3 is expressed as offset X. Notably, expression of the horizontal axis (position in the y-direction) and the vertical axis (Bragg wavelength) is omitted.

FIG. 11(b) shows a situation where an offset Y in the reverse direction to that of the offset X is provided. The offset Y restrains higher-order mode oscillation on the short wavelength side.

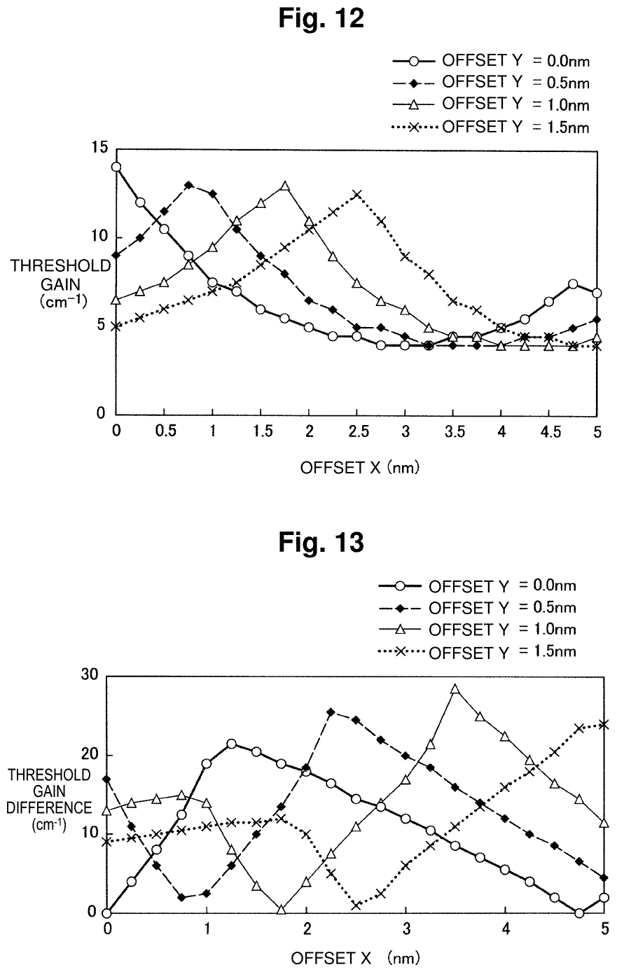

FIG. 12 is a diagram showing results of calculation of change in threshold gain in the fundamental mode versus change in offset X with the offset Y being as a parameter. The horizontal axis represents the offset X (nm), and the vertical axis represents the threshold gain (cm⁻¹) in the fundamental mode.

There are shown characteristics as shown in FIG. 12 in which the threshold gain decreases in response to increase of the offset X when the offset Y is not provided. They change to characteristics in which the threshold gain has a peak when the offset Y is provided.

FIG. 13 is a diagram showing results of calculation of change in threshold gain difference between the fundamental mode and the higher-order mode versus change in offset X with the offset Y being as a parameter. The horizontal axis represents the offset X (nm), the vertical axis represents the threshold gain difference (cm⁻¹) between the fundamental mode and the higher-order mode.

It is clear as shown in FIG. 13 that providing the offset Y can enlarge the threshold gain difference between the fundamental mode and the higher-order mode. The threshold gain difference is 22 cm⁻¹ at the offset Y=0.0 nm, the threshold gain difference is 26 cm⁻¹ at the offset Y=0.5 nm, the threshold gain difference is 28 cm⁻¹ at the offset Y=1.0 nm, and the threshold gain difference is 25 cm⁻¹ at the offset Y=1.5 nm.

As above, providing the offset Y can reduce a resonator loss in the fundamental mode, and meanwhile, can enlarge the threshold gain difference between the fundamental mode and the higher-order mode. Accordingly, the narrow line width can be made compatible with stabilization of the oscillation mode.

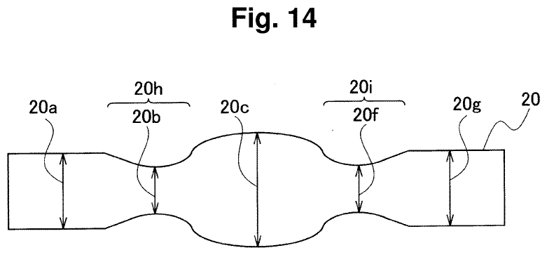

FIG. 14 is a view schematically showing an example of the planar shape of the optical waveguide 20 that has two of the offset X and the offset Y provided. The optical waveguide 20 having the offsets X and Y provided is different in including a second portion 20b having a smaller width than the width of the first portion 20a, a fourth portion 20d having a smaller width than the width of the third portion 20c, and a fifth portion 20d having the same width as the width of the first portion 20a.

The optical waveguide 20 shown in FIG. 14 includes, in the extending direction, the first portion 20a having a predetermined width, the second portion 20b having a smaller width than the width of the first portion 20a, the third portion 20c having a larger width than the width of the first portion 20a, the fourth portion 20f having a smaller width than the width of the third portion 20c, and the fifth portion 20g having the same width as the width of the first portion 20a, and includes a first connection portion 20h connecting smoothly between the first portion 20a and the third portion 20c, and a second connection portion 20i connecting smoothly between the third portion 20c and the fifth portion 20g. This can make the narrow line width compatible with stabilization of the oscillation mode.

### (Modification 1)

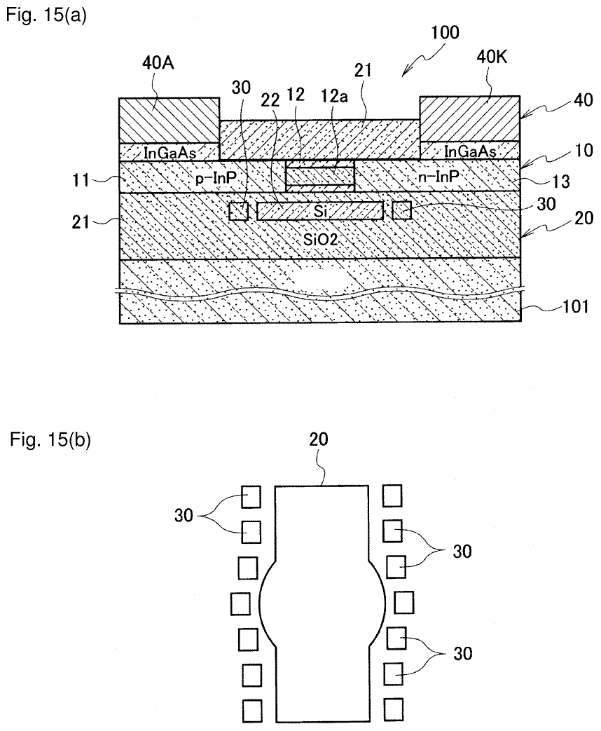

FIG. 15 exemplarily shows a sectional configuration of a modification of the semiconductor optical device 100. In Modification 1 shown in FIG. 15, uniform diffraction gratings 30 are arranged on the same plane where the silicon core 22 (FIG. 7) is.

As shown in FIG. 15, the uniform diffraction gratings 30 may be arranged on both sides along the extending direction (y) of the optical waveguide 20. The same operation and effects as in the aforementioned embodiment (FIG. 7) can be obtained even when the uniform diffraction gratings 30 are arranged as above.

### (Modification 2)

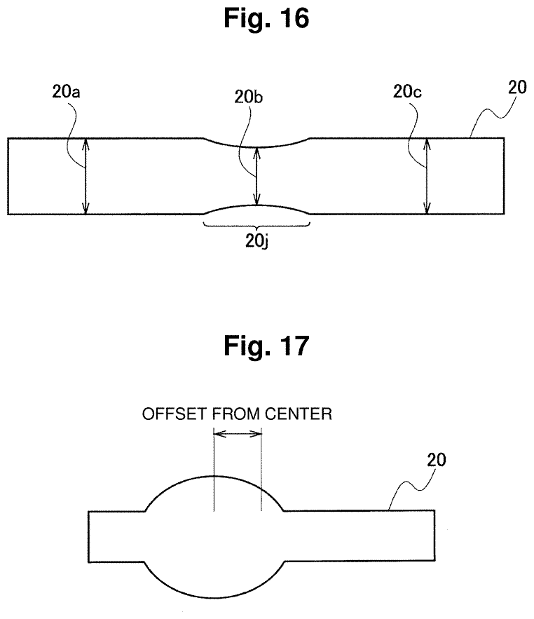

FIG. 16 is a view schematically showing a planar shape of a modification of the optical waveguide 20. The optical waveguide 20 of Modification 2 shown in FIG. 16 is different from that of the aforementioned embodiment in that the width of the second portion 20b is smaller than the width of the first portion 20a.

The optical waveguide 20 shown in FIG. 16 includes, in the extending direction, the first portion 20a having a predetermined width, the second portion 20b having a smaller width than the width of the first portion 20a, and the third portion 20c having the same width as the width of the first portion 20a, and includes a connection portion 20j smoothly connecting the first portion 20a, the second portion 20b and the third portion 20c. As above, the width of the center portion of the optical waveguide 20 in the y-direction may be made small. Making the width of the second portion 20b smaller than the width of the first portion 20a can provide a band offset with which the long wavelength side is selected.

### (Modification 3)

FIG. 17 is a view schematically shows a planar shape of another modification of the optical waveguide 20. The optical waveguide 20 of Modification 3 shown in FIG. 17 is different from that of the aforementioned embodiment in that the position of the first portion 20a is displaced from the center of the optical waveguide 20 in the y-direction.

Displacing the position of the first portion 20a from the center of the optical waveguide 20 in the y-direction as shown in FIG. 17 can enhance one of the reflectances of the optical waveguide 20, and the direction of emission of laser light can be selected.

As described above, the semiconductor optical device 100 according to the present embodiment can realize a semiconductor optical device high in spatial hole burning tolerance and effective for achieving laser light with the narrow line width. Moreover, since the uniform diffraction grating 30 is used, the production is easier than in the case using the λ/4 shift diffraction grating, and the production yield of semiconductor optical devices can be improved, resulting in cost reduction.

Notably, the optical waveguide 20 is presented as an example of including the silicon core 22 and the cladding layer 21 composed of a SiO₂ film. The optical waveguide 20 as this example can be easily produced. It should be noted that the present invention is not limited to this example. The optical waveguide 20 may be composed using any material as long as it is a material used for an optical waveguide, such as, for example, a SiN core, an AiN core, a SiOx cladding and a SiC cladding.

Moreover, the aforementioned embodiment is presented as an example in which the width in the direction perpendicular to the extending direction (y) of the optical waveguide 20 is caused to vary, not limited to this example. For example, the thickness or the material refractive index of the optical waveguide 20 in the extending direction (y) may be caused to vary. Moreover, while it has been described that the width widening region 20d, the width narrowing region 20e, the first connection portion 20h, the second connection portion 20i and the connection portion 20j connect smoothly between the first portion 20a, the second portion 20b and the like, such smooth portions may be connected by any function such as a Gaussian function, a parabolic function, an Nth-degree function and a trigonometric function.

As above, it is needless to say that the present invention includes various embodiments and the like not mentioned here.

Accordingly, the technical scope of the present invention is defined only by the matters specifying the invention which are reasonable from the description above and in accordance with the claims.

### REFERENCE SIGNS LIST

10 Light emitting layer

12a Active layer

20 Optical waveguide

20a First portion

20b Second portion

20c Third portion

20d Width widening region

20e Width narrowing region

20f Fourth portion

20g Fifth portion

20h First connection portion

20i Second connection portion

20j Connection portion

30 Uniform diffraction grating

40 Electrode unit

40A Anode electrode

40K Cathode electrode

100 Semiconductor optical device

1. A semiconductor optical device comprising:
a light emitting layer that emits light in a state of current injection;
an optical waveguide in which a width or a thickness in an extending direction of the light emitting layer varies along the extending direction; and
a uniform diffraction grating having constant cycle, width and depth, wherein
the light emitting layer, the optical waveguide, and the uniform diffraction grating are arranged at positions where the light emitting layer, the optical waveguide, and the uniform diffraction grating are optically coupled to one another.

2. The semiconductor optical device according to claim 1, wherein the uniform diffraction grating is arranged above the light emitting layer, and the optical waveguide is arranged below the light emitting layer.

3. The semiconductor optical device according to claim 1, wherein
the optical waveguide includes, in the extending direction, a first portion having a predetermined width, a second portion having a larger width than the width of the first portion, and a third portion having the same width as the width of the first portion, and includes
a width widening region connecting smoothly between the first portion and the second portion, and a width narrowing region connecting smoothly between the second portion and the third portion.

4. The semiconductor optical device according to claim 1, wherein
the optical waveguide includes, in the extending direction, a first portion having a predetermined width, a second portion having a smaller width than the width of the first portion, a third portion having a larger width than the width of the first portion, a fourth portion having a smaller width than the width of the third portion, and a fifth portion having the same width as the width of the first portion, and includes
a first connection portion connecting smoothly between the first portion and the third portion, and a second connection portion connecting smoothly between the third portion and the fifth portion.

5. The semiconductor optical device according to claim 1, wherein
the optical waveguide includes, in the extending direction, a first portion having a predetermined width, a second portion having a smaller width than the width of the first portion, and a third portion having the same width as the width of the first portion, and includes
a connection portion smoothly connecting the first portion, the second portion and the third portion.

6. The semiconductor optical device according to claim 3, wherein widths at both end portions in the extending direction of the optical waveguide are larger than the width of the first portion.

7. The semiconductor optical device according to claim 1, wherein the optical waveguide includes a silicon core and a SiO₂ cladding.

8. The semiconductor optical device according to claim 2, wherein
the optical waveguide includes, in the extending direction, a first portion having a predetermined width, a second portion having a larger width than the width of the first portion, and a third portion having the same width as the width of the first portion, and includes
a width widening region connecting smoothly between the first portion and the second portion, and a width narrowing region connecting smoothly between the second portion and the third portion.

9. The semiconductor optical device according to claim 2, wherein
the optical waveguide includes, in the extending direction, a first portion having a predetermined width, a second portion having a smaller width than the width of the first portion, a third portion having a larger width than the width of the first portion, a fourth portion having a smaller width than the width of the third portion, and a fifth portion having the same width as the width of the first portion, and includes
a first connection portion connecting smoothly between the first portion and the third portion, and a second connection portion connecting smoothly between the third portion and the fifth portion.

10. The semiconductor optical device according to claim 2, wherein
the optical waveguide includes, in the extending direction, a first portion having a predetermined width, a second portion having a smaller width than the width of the first portion, and a third portion having the same width as the width of the first portion, and includes
a connection portion smoothly connecting the first portion, the second portion and the third portion.

11. The semiconductor optical device according to claim 2, wherein the optical waveguide includes a silicon core and a SiO₂ cladding.

12. The semiconductor optical device according to claim 3, wherein the optical waveguide includes a silicon core and a SiO₂ cladding.

13. The semiconductor optical device according to claim 4, wherein the optical waveguide includes a silicon core and a SiO₂ cladding.

14. The semiconductor optical device according to claim 5, wherein the optical waveguide includes a silicon core and a SiO₂ cladding.

15. The semiconductor optical device according to claim 6, wherein the optical waveguide includes a silicon core and a SiO₂ cladding.
